(19) United States
(12) Patent Application Publication
(10) Pub. No.: US 2025/0057008 A1
(43) Pub. Date: Feb. 13, 2025

(54) DISPLAY PANEL AND METHOD FOR MANUFACTURING THE SAME

(71) Applicant: Samsung Display Co., LTD., Yongin-si (KR)

(72) Inventor: DASOL JEONG, Yongin-si (KR)

(21) Appl. No.: 18/737,734

(22) Filed: Jun. 7, 2024

(30) Foreign Application Priority Data
Aug. 10, 2023 (KR) 10-2023-0105050

(51) Int. Cl. H10K 59/80; G02B 27/01; H10K 50/844; H10K 59/122; H10K 59/38; H10K 102/10

(52) U.S. Cl. CPC H10K 59/80518; G02B 27/0172; H10K 50/844; H10K 59/122; H10K 59/38; H10K 59/80524; H10K 2102/101

(57) ABSTRACT

A display panel includes: a base layer including a display region including a first light-emitting region, a second light-emitting region, and a non-light-emitting region, and a non-display region; a first lower electrode on the base layer, overlapping the first light-emitting region, and including a first reflective electrode and a first transparent electrode on the first reflective electrode; a second lower electrode on the base layer, overlapping the second light-emitting region, and including a second reflective electrode and a second transparent electrode on the second reflective electrode; and a first inorganic film overlapping the first light-emitting region, and at least partially between the first reflective electrode and the first transparent electrode, wherein the first inorganic film is spaced apart from the second reflective electrode with a first gap therebetween.

### CROSS-REFERENCE TO RELATED APPLICATIONS

The present application claims priority to and the benefit of Korean Patent Application No. 10-2023-0105050, filed on Aug. 10, 2023, in the Korean Intellectual Property Office, the entire disclosure of which is incorporated herein by reference.

### BACKGROUND

### 1. Field

Aspects of some embodiments of the present disclosure herein relate to a display panel and a method for manufacturing the same.

### 2. Description of the Related Art

A display device, which display images to users, such as a television, a monitor, a smartphone, and a tablet computer includes a display panel that displays the images. As the display panel, various display panels such as liquid crystal display panels, organic light-emitting display panels, electro-wetting display panels, and electrophoretic display panels are being developed.

Various methods for patterning a light-emitting element may enable relatively improved reliability of the display panel, and recently, research on a high-resolution display device including a light-emitting material commonly supplied by using an open-mask is being conducted.

The above information disclosed in this Background section is only for enhancement of understanding of the background and therefore the information discussed in this Background section does not necessarily constitute prior art.

### SUMMARY

Aspects of some embodiments of the present disclosure herein relate to a display panel and a method for manufacturing the same, and for example, to a display panel having relatively improved durability and reliability.

Aspects of some embodiments of the present disclosure include a display panel having relatively improved durability and reliability while achieving relatively high-resolution, and a method for manufacturing the same.

According to some embodiments of the present disclosure, a display panel includes: a base layer including a display region including a first light-emitting region, a second light-emitting region, and a non-light-emitting region, and a non-display region, a first lower electrode on the base layer, overlapping the first light-emitting region, and including a first reflective electrode and a first transparent electrode on the first reflective electrode, a second lower electrode on the base layer, overlapping the second light-emitting region, and including a second reflective electrode and a second transparent electrode on the second reflective electrode, and a first inorganic film overlapping the first light-emitting region, and at least partially between the first reflective electrode and the first transparent electrode, wherein the first inorganic film is spaced apart from the second reflective electrode with a first gap therebetween.

According to some embodiments, the first inorganic film may cover an upper surface and side surfaces of the first reflective electrode.

According to some embodiments, the first inorganic film may include at least one of silicon dioxide (SiOₓ), silicon nitride (SiNₓ), or silicon oxynitride (SiOₓN_{y}).

According to some embodiments, the display panel may further include a second inorganic film overlapping the first light-emitting region and the second light-emitting region, and at least partially on the first reflective electrode and the second reflective electrode.

According to some embodiments, the second inorganic film may be respectively between the first reflective electrode and the first transparent electrode, and between the second reflective electrode and the second transparent electrode.

According to some embodiments, the display region may further include a third light-emitting region, and the display panel may further include a third lower electrode on the base layer, overlapping the third light-emitting region, and including a third reflective electrode and a third transparent electrode on the third reflective electrode.

According to some embodiments, the second inorganic film may be spaced apart from the third reflective electrode with a second gap therebetween.

According to some embodiments, the third transparent electrode may be directly on the third reflective electrode.

According to some embodiments, a first distance between the first reflective electrode and the first transparent electrode in a thickness direction of the display panel may be greater than a second distance between the second reflective electrode and the second transparent electrode in the thickness direction.

According to some embodiments, the first lower electrode and the second lower electrode may respectively include a first layer including a transparent conductive oxide, a second layer on the first layer, and including a reflective metal material, and a third layer on the second layer, and including a transparent conductive oxide.

According to some embodiments, the display panel may further include a pixel-defining film at least partially covering each of the first transparent electrode and the second transparent electrode, and including an inorganic material.

According to some embodiments, the display panel may further include at least one organic layer on the first transparent electrode and the second transparent electrode, and including a light-emitting layer, and an upper electrode on the at least one organic layer.

According to some embodiments, the display panel may further include an encapsulation layer on the upper electrode, and a plurality of color filters on the encapsulation layer, and in each of the first light-emitting region and the second light-emitting region.

According to some embodiments, the first reflective electrode and the second reflective electrode may be spaced apart from each other in a plan view, and on a same layer.

According to some embodiments, the first transparent electrode may be in contact with the reflective electrode through a first contact penetrating the first inorganic film.

According to some embodiments of the present disclosure, a display panel includes a base layer including a display region including a first light-emitting region, a second light-emitting region, a third light-emitting region, and a non-light-emitting region, and a non-display region, a first reflective electrode on the base layer, and overlapping the first light-emitting region, a second reflective electrode on the base layer, and overlapping the second light-emitting region, a third reflective electrode on the base layer, and overlapping the third light-emitting region, a first inorganic film overlapping the first light-emitting region, and at least partially on the first reflective electrode, and a second inorganic film overlapping the first light-emitting region and the second light-emitting region, and at least partially on the second reflective electrode, wherein the first inorganic film is spaced apart from the second reflective electrode with a first gap therebetween, and the second inorganic film is spaced apart from the third reflective electrode with a second gap therebetween.

According to some embodiments, the first inorganic film may cover an upper surface and side surfaces of the first reflective electrode, and the second inorganic film may cover an upper surface and side surfaces of the second reflective electrode.

According to some embodiments, the method includes providing a preliminary display panel including a base layer, a first reflective electrode on the base layer, and a second reflective electrode on the base layer and spaced apart from the first reflective electrode, forming a first preliminary inorganic film so as to respectively cover the first reflective electrode and the second reflective electrode, and forming a first inorganic film by patterning the first preliminary inorganic film so as to partially remove the first preliminary inorganic film formed on the second reflective electrode, wherein in the forming of the first inorganic film, the first inorganic film and the second reflective electrode are patterned to be spaced apart from each other with a first gap therebetween.

According to some embodiments, the method may further include, after the forming of the first inorganic film, forming a second preliminary inorganic film on the first inorganic film so as to cover the second reflective electrode, and forming a second inorganic film by patterning the second preliminary inorganic film.

According to some embodiments, the preliminary display panel may be on the first base layer, and further include a third reflective electrode spaced apart from the first reflective electrode and the second reflective electrode, in the forming of the second preliminary inorganic film, the second preliminary inorganic film is formed so as to cover the third reflective electrode, and in the forming of the second inorganic film, the second inorganic film and the third reflective electrode are patterned to be spaced apart from each other with a second gap therebetween.

### BRIEF DESCRIPTION OF THE DRAWINGS

The accompanying drawings are included to provide a further understanding of embodiments according to the present disclosure, and are incorporated in and constitute a part of this specification. The drawings illustrate aspects of some embodiments of the present disclosure and, together with the description, serve to explain aspects of some embodiments of the present disclosure. In the drawings:

FIG. 1 is a perspective view illustrating an electronic device according to some embodiments of the present disclosure;

FIG. 2A is a perspective view illustrating an electronic device according to some embodiments of the present disclosure;

FIG. 2B is an exploded perspective view of an electronic device according to some embodiments of the present disclosure;

FIG. 3 is a plan view of a display panel according to some embodiments of the present disclosure;

FIG. 4 is a cross-sectional view of a display panel according to some embodiments of the present disclosure;

FIGS. 5A and 5B are respectively enlarged cross-sectional views of some configurations of a display panel according to some embodiments of the present disclosure;

FIG. 6 is a cross-sectional view of a display panel according to some embodiments of the present disclosure;

FIGS. 7A and 7B are cross-sectional views of a light-emitting element according to some embodiments of the present disclosure;

FIG. 8 is a flowchart of a method for manufacturing a display panel according to some embodiments of the present disclosure; and

FIGS. 9A to 9H are cross-sectional views of some operations of a method for manufacturing a display panel according to some embodiments of the present disclosure.

### DETAILED DESCRIPTION

In this specification, when a component (or region, layer, portion, etc.) is referred to as “on”, “connected”, or “coupled” to another component, it means that it is placed/connected/coupled directly on the other component or a third component can be located between them.

The same reference numerals or symbols refer to the same elements. In addition, in the drawings, thicknesses, ratios, and dimensions of components are exaggerated for effective description of technical content. “And/or” includes all combinations of one or more that the associated elements may define.

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “include” or “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

In the present application, “be directly located” may mean that there is no layer, film, region, plate, etc. added between a portion such as a layer, film, region, or plate and another portion. For example, “be directly located” may mean placing two layers or two members without using an additional member such as an adhesive member therebetween.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Hereinafter, an electronic device according to some embodiments of the present disclosure and a display panel included in the same will be described in more detail with reference to the drawings.

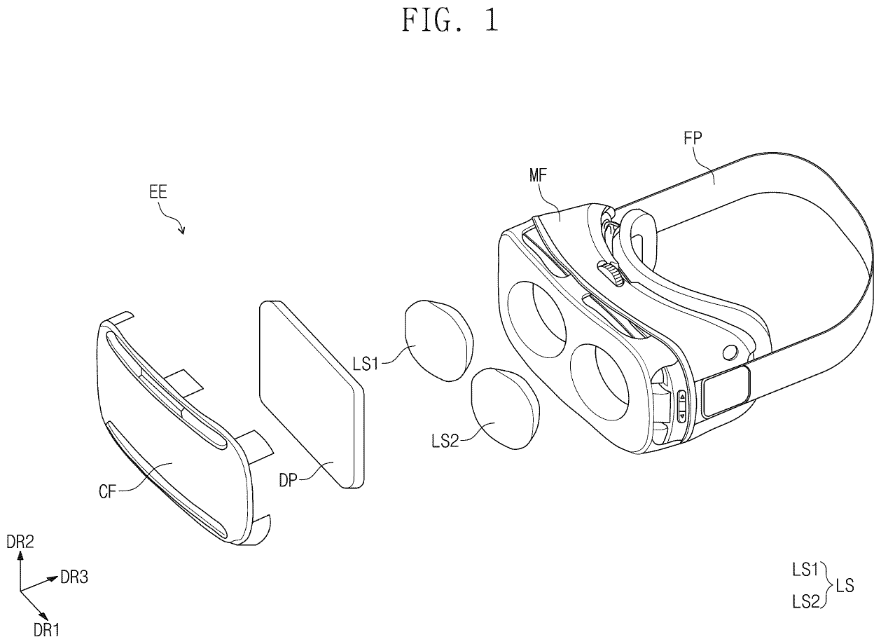

FIG. 1 is a perspective view illustrating an electronic device EE according to some embodiments of the present disclosure. The electronic device EE may be activated in response to an electrical signal. For example, the electronic device EE may be a television, a monitor, a billboard, a game console, a personal computer, a notebook computer, a mobile phone, a tablet computer, a navigation system, and a wearable device, but embodiments according to the present disclosure are not limited thereto.

FIG. 1 illustrates a head mounted display (HMD) device as an example of the electronic device EE. The head mounted display device may be a device mounted on a user's head to supply, to the user, a screen where an image or a video is displayed. The head mounted display device may include a see-through type supplying augmented reality (AR) on the basis of real external objects, and a see-closed type supplying, to a user, virtual reality (VR) on a screen independent of an external object.

Referring to FIG. 1, the electronic device EE may include a display panel DP and a lens portion LS opposed to the display panel DP. In addition, the electronic device EE may include a main frame MF, a cover frame CF, and a fixing part FP.

The main frame MF may be attached to a user's face. The main frame MF may have a shape corresponding to a shape of a user's head (face). For example, a length of the fixing part FP may be controlled according to a circumference of the user's head. The fixing part FP, which is a structure facilitating attachment of the main frame MF, may include a strap, a band, or the like. However, embodiments according to the present disclosure are not limited thereto, and the fixing part FP may have various forms such as a helmet or eyeglass temples coupled to the main frame MF.

The lens portion LS, the display panel DP, and the cover frame CF may be mounted on the main frame MF. The main frame MF may include a space or a structure in which the lens portion LS and the display panel DP may be accommodated.

The lens portion LS may be located between the display panel DP and a user. Light incident from the display panel DP may penetrate the lens portion LS, and be supplied to the user. For example, the lens portion LS may include various types of lenses such as multi-channel lenses, convex lenses, concave lenses, spherical lenses, aspherical lenses, single lenses, compound lenses, standard lenses, narrow-angle lenses, wide-angle lenses, fixed focus lenses, or varifocal lenses.

The lens portion LS may include a first lens LS1 and a second lens LS2. The first lens LS1 and the second lens LS2 may be respectively arranged to correspond to a position of a left eye and a position of a right eye of the user. The first lens LS1 and the second lens LS2 may be accommodated inside the main frame MF.

The display panel DP may be provided in a state of being fixed to the main frame MF, or a state of being attachable or detachable to the main frame MF. The display panel DP will be described in more detail later.

The cover frame CF may be located on one surface of the display panel DP to protect the display panel DP. The cover frame CF and the lens portion LS may be spaced apart from each other with the display panel DP therebetween.

FIG. 1 and the following drawings illustrate a first direction DR1 to a third direction DR3, and directions indicated by the first to third directions DR1, DR2, and DR3 described in this specification are relative concepts, and may be changed to other directions. In addition, the directions indicated by the first to third directions DR1, DR2, and DR3 may be described as the first to third directions, and the same reference numerals or symbols may be used. In this specification, the first direction DR1 and the second direction DR2 may be perpendicular to each other, and the third direction DR3 may be a normal direction to a plane defined by the first direction DR1 and the second direction DR2.

A thickness direction of the electronic device EE may be parallel to the third direction DR3 which is a normal direction of the plane defined by the first direction DR1 and the second direction DR2. In this specification, the front surface (or upper surface) and the rear surface (or lower surface) of members constituting the electronic device EE may be defined with respect to the third direction DR3. In this specification, “on a plane” or “in a plan view” refers to a view perpendicular to a surface parallel to a plane defined by the first direction DR1 and the second direction DR2, and “on a cross-section” means a surface parallel to the third direction DR3.

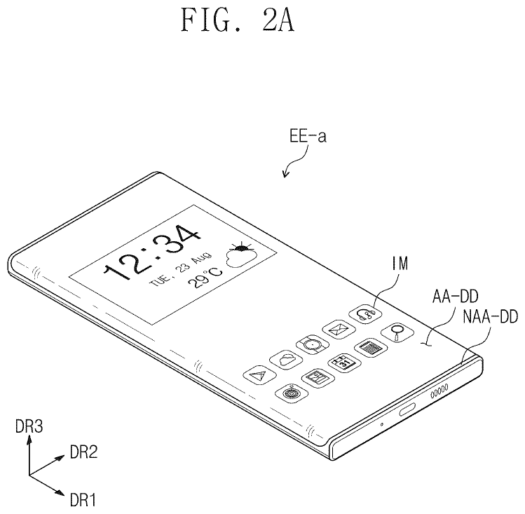

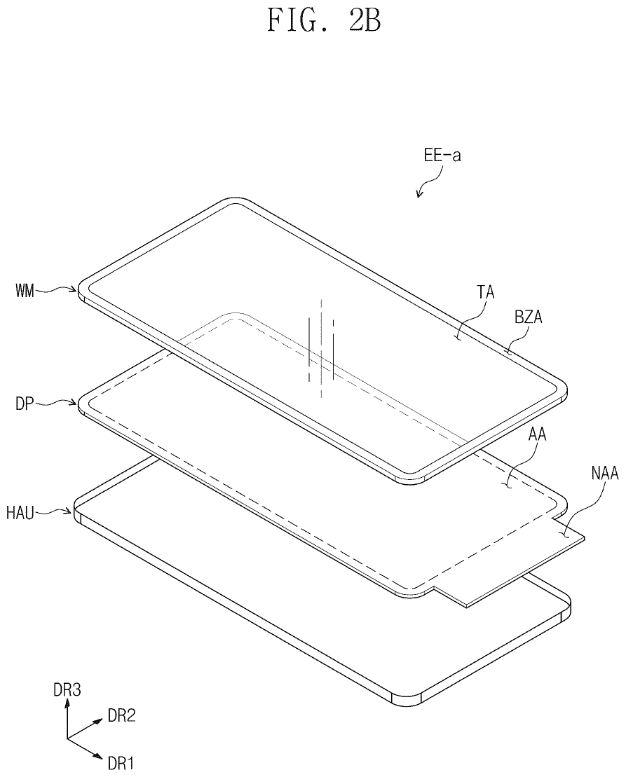

FIG. 2A is a perspective view illustrating an electronic device EE-a according to some embodiments of the present disclosure. FIG. 2A is a perspective view illustrating an electronic device according to some embodiments of the present disclosure, and illustrates a mobile phone as an example of the electronic device EE-a. The electronic device EE-a may display an image IM through an active region AA-DD. The active region AA-DD may include a plane defined by the first direction DR1 and the second direction DR2. The active region AA-DD may include a curved surface bent from at least one side of the plane defined by the first direction DR1 and the second direction DR2. However, this is an example, and a shape of the active region AA-DD is not limited thereto. For example, the active region AA-DD may include only the plane, or may further include at least two curved surfaces of the plane, for example, four curved surfaces respectively bent from four side surfaces.

The peripheral region NAA-DD is adjacent to the active region AA-DD. The peripheral region NAA-DD may surround the active region AA-DD. Accordingly, a shape of the active region AA-DD may be substantially defined by the peripheral region NAA-DD. However, this is merely an example, and the peripheral region NAA-DD may be located adjacent to one side of the active region AA-DD, or may be omitted. The active region AA-DD may be provided with various shapes, and is not limited to any one embodiment.

FIG. 2B is an exploded perspective view of the electronic device EE-a illustrated in FIG. 2A. Referring to FIG. 2B, the electronic device EE-a may include a housing HAU, a display panel DP, and a window member WM.

The window member WM may cover the total exterior of the display panel DP. The window member WM may include a transmission region TA and a bezel region BZA. The front surface of the window member WM including the transmission region TA and the bezel region BZA may correspond to the front surface of the electronic device EE-a. The transmission region TA may correspond to the active region AA-DD of the electronic device EE-a illustrated in FIG. 2A, and the bezel region BZA may correspond to the peripheral region NAA-DD of the electronic device EE-a illustrated in FIG. 2A.

The transmission region TA may be optically transparent. The bezel region BZA may be a region having a relatively lower transmittance than the transmission region TA. For example, according to some embodiments the bezel region BZA may not transmit light. The bezel region BZA may have a color (e.g., a set or predetermined color). The bezel region BZA may be adjacent to the transmission region TA, and may surround the transmission region TA. The bezel region BZA may define a shape of the transmission region TA, but embodiments according to the present disclosure are not limited thereto. The bezel region BZA may be located adjacent to one side of the transmission region TA, and a portion thereof may be omitted.

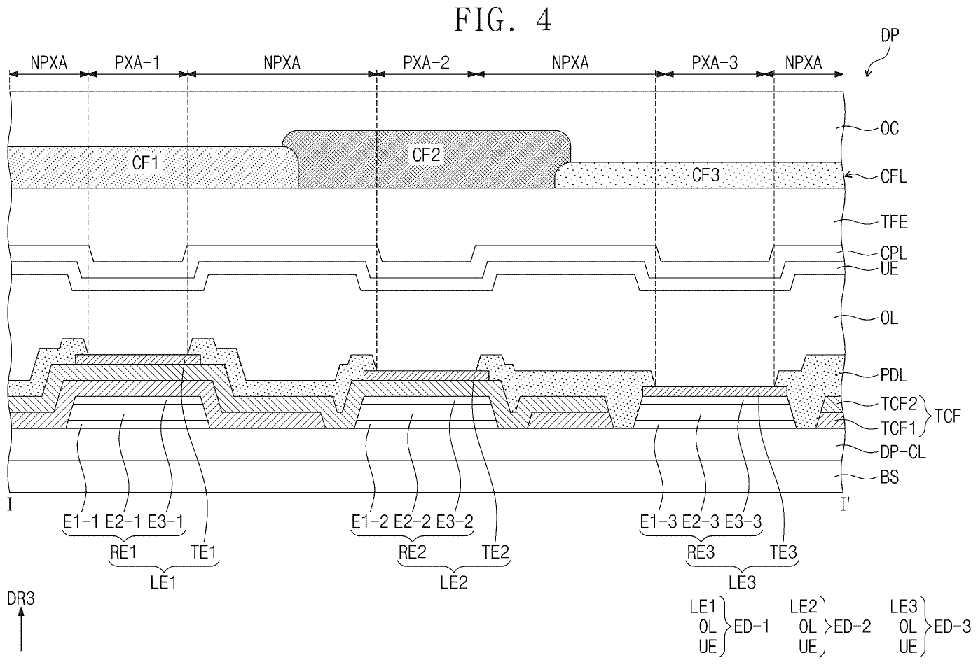

According to some embodiments, an input-sensing portion may be provided on the display panel DP. The input-sensing portion may sense an external input applied from the outside. The external input may be a user's input. The user's input may include various forms of external inputs such as a part of a user's body, light, heat, pen, or pressure. For example, the input-sensing portion may be located on an encapsulation layer TFE (see FIG. 4) of the display panel DP to be described in more detail later. Alternatively, the input-sensing portion may be directly located on the encapsulation layer TFE (see FIG. 4), or may be directly located on an adhesive member located on the encapsulation layer TFE (see FIG. 4). The adhesive member may include a typical adhesive or bonding agent.

In this specification, one component (region, layer, part, or the like) is “directly located” on another component means that no third component is located between the one component and the other component. That is, one component is “directly located” on another component means that the one component and the other component are in “contact” with each other.

The housing HAU may accommodate the display panel DP, etc. The housing HAU may be coupled to the window member WM.

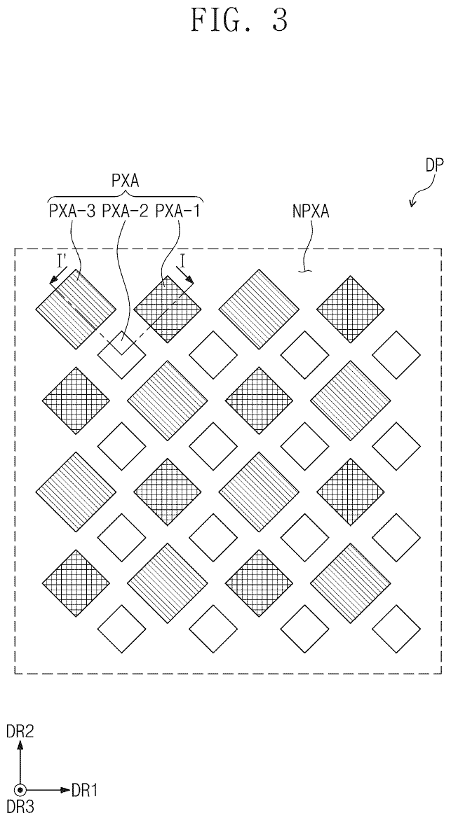

FIG. 3 is a plan view illustrating a display panel DP according to some embodiments of the present disclosure. Hereinafter, description for the display panel DP may be equally applied to the display panel DP included by electronic devices EE and EE-a illustrated in FIGS. 1 and 2B.

Referring to FIG. 3, the display panel DP may include a light-emitting region PXA and a non-light-emitting region NPXA. The non-light-emitting region NPXA may surround the light-emitting region PXA. The light-emitting region PXA may be provided in plurality. The light-emitting region PXA may include a first light-emitting region PXA-1, a second light-emitting region PXA-2, and a third light-emitting region PXA-3. The first light-emitting region PXA-1, the second light-emitting region PXA-2, and the third light-emitting region PXA-3 may respectively emit light having wavelength regions different from each other. The first light-emitting region PXA-1 may emit first light, and the second light-emitting region PXA-2 may emit second light different from the first light. The third light-emitting region PXA-3 may emit third light different from the first light and the second light. Meanwhile, the first light may be red light, the second light may be green light, and the third light may be blue light.

Among the first to third light-emitting regions PXA-1, PXA-2, and PXA-3, the third light-emitting region PXA-3 may have the largest area, and the second light-emitting region PXA-2 may have the smallest area. However, this is an example, and areas of the first to third light-emitting regions PXA-1, PXA-2, and PXA-3 are not limited thereto. FIG. 3 illustrates that the first light-emitting region PXA-1 and the third light-emitting region PXA-3 are alternately arranged in one row, and the second light-emitting region PXA-2 is spaced apart from the first light-emitting region PXA-1 and the second light-emitting region PXA-2 to be arranged in another row. However, this is an example, and an arrangement of the first to third light-emitting regions PXA-1, PXA-2, and PXA-3 is not limited thereto.

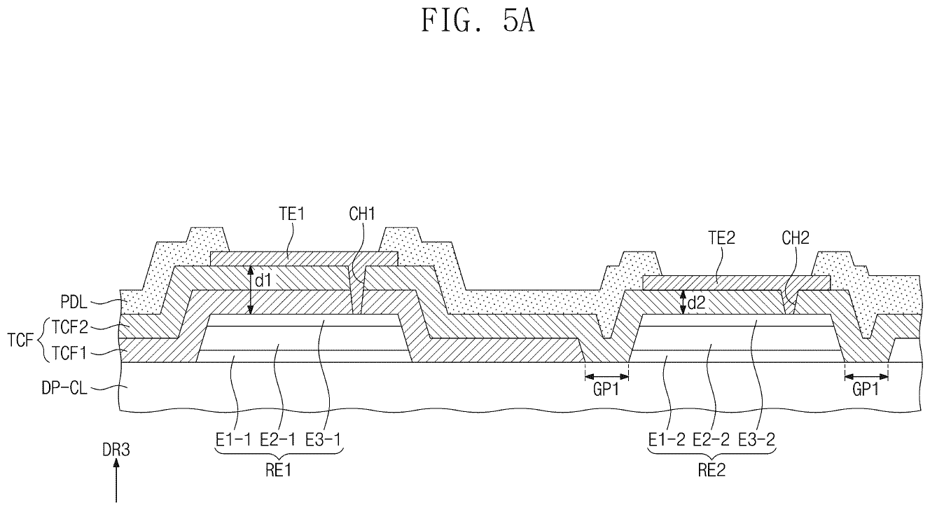

FIG. 4 is a cross-sectional view of a display panel according to some embodiments of the present disclosure. FIGS. 5A and 5B are enlarged cross-sectional views of some configurations of the display panel according to some embodiments of the present disclosure, respectively. FIG. 4 is a cross-sectional view illustrating a portion corresponding to line I-I′ in FIG. 3. FIG. 5A is an enlarged view of a first lower electrode LE1 and a second lower electrode LE2 included in a display panel DP in FIG. 4. FIG. 5B is an enlarged view of the second lower electrode LE2 and a third lower electrode LE3 included in the display panel DP in FIG. 4.

Referring to FIG. 4, the display panel DP may include a base layer BS, a circuit layer DP-CL located on the base layer BS, a display element layer DP-ED located on the circuit layer DP-CL, and an encapsulation layer TFE located on the display element layer DP-ED. In addition, the display panel DP may further include a color filter layer CFL located on the encapsulation layer TFE.

Referring to FIG. 4, the base layer BS may be a member supplying a base surface on which the circuit layer DP-CL is located. The base layer BS may be a rigid substrate, or a flexible substrate bendable, foldable, or rollable. The base layer BS may be a glass substrate, a metal substrate, a polymer substrate or the like. However, embodiments according to the present disclosure are not limited thereto, and the base layer BS may be an inorganic layer, an organic layer, or a composite material layer.

The base layer BS may include a single layer or a multiple layer. For example, the base layer BS may include a first synthetic resin layer, an intermediate layer having a single-layered or multi-layered structure, and a second synthetic resin layer sequentially stacked. The intermediate layer may be referred to as a base barrier layer. The intermediate layer may include a silicon oxide (SiOₓ) layer and an amorphous silicon (a-Si) layer located on the silicon oxide layer, but is not specially limited thereto. For example, the intermediate layer may include at least one of a silicon oxide layer, a silicon nitride layer, a silicon oxynitride layer, or an amorphous silicon layer.

The first and second synthetic resin layers may each include a polyimide-based resin. In addition, the first and second synthetic resin layers may each include at least one of an acrylic resin, a methacrylate resin, a polyisoprene-based resin, a vinyl-based resin, an epoxy-based resin, a urethane-based resin, a cellulose-based resin, a siloxane-based resin, a polyamide-based resin, or a perylene-based resin. In this specification, “an X-based resin” means a resin including “functional group X”.

The circuit layer DP-CL may be located on the base layer BS. The circuit layer DP-CL may include an insulating layer, a semiconductor pattern, a conductive pattern, a signal line, etc. After an insulating layer, a semiconductor layer, and a conductive layer are formed on the base layer BS in a method such as coating and deposition, the insulating layer, the semiconductor layer, and the conductive layer may be selectively patterned through a plurality times of photolithography processes. Thereafter, the semiconductor pattern, the conductive pattern, and the signal line included in the circuit layer DP-CL may be formed.

According to some embodiments, the base layer BS may be a silicon substrate. The base layer BS may be a monocrystalline silicon wafer, a polycrystalline silicon wafer, or an amorphous silicon wafer. The circuit layer DP-CL may include the insulating layer, the semiconductor pattern, the conductive pattern, the signal line, etc.

The display element layer DP-ED may be located on the circuit layer DP-CL. The display element layer DP-ED may include first to third light-emitting elements ED-1, ED-2, and ED-3, an inorganic film TCF, a pixel-defining film PDL, and a capping layer CPL.

The first to third light-emitting elements ED-1, ED-2, and ED-3 may be spaced apart from each other in a direction crossing the third direction DR3. The first to third light-emitting elements ED-1, ED-2, and ED-3 may respectively include lower electrodes LE1, LE2, and LE3, an organic layer OL located on the lower electrodes LE1, LE2, and LE3, and an upper electrode UE located on the organic layer OL. In addition, the display element layer DP-ED may include the capping layer CPL located on the upper electrode UE.

Referring to FIGS. 4, 5A, and 5B together, the lower electrodes LE1, LE2, and LE3 may respectively include reflective electrodes RE1, RE2, and RE3 located on the circuit layer DP-CL, and transparent electrodes TE1, TE2, and TE3 respectively located on the reflective electrodes RE1, RE2, and RE3. Meanwhile, in this specification, the lower electrodes LE1, LE2, and LE3 may mean “anodes”. The lower electrodes LE1, LE2, and LE3 may respectively include stack structures of the reflective electrodes RE1, RE2, and RE3 and the transparent electrodes TE1, TE2, and TE3.

The reflective electrodes RE1, RE2, and RE3 may include a first reflective electrode RE1 included in a first light-emitting element ED-1, a second reflective electrode RE2 included in a second light-emitting element ED-2, and a third reflective electrode RE3 included in a third light-emitting element ED-3.

The first reflective electrode RE1, the second reflective electrode RE2, and the third reflective electrode RE3 may respectively include an electrode having a three-layered structure. The first reflective electrode RE1, the second reflective electrode RE2, and the third reflective electrode RE3 may respectively include first layers E1-1, E1-2, and E1-3, second layers E2-1, E2-2, and E2-3, and third layers E3-1, E3-2, and E3-3 which are sequentially stacked. The first layers E1-1, E1-2, and E1-3 and the third layers E3-1, E3-2, and E3-3 may each include a transparent conductive oxide. The first layers E1-1, E1-2, and E1-3 and the third layers E3-1, E3-2, and E3-3 may each include at least one selected from a group including indium-tin oxide (ITO), indium-zinc oxide (IZO), indium-gallium-zinc oxide (IGZO), zinc oxide (ZnOₓ), or indium oxide (In₂O₃), and aluminum-doped zinc oxide (AZO). For example, the first layers E1-1, E1-2, and E1-3 and the third layers E3-1, E3-2, and E3-3 may each include indium-tin oxide (ITO), or indium-zinc oxide (IZO).

The second layers E2-1, E2-2, and E2-3 may include a reflective metal material. The second layers E2-1, E2-2, and E2-3 may include metal having a high reflectance, an oxide of the metal having a high reflectance, a nitride of the metal having a high reflectance, or the like. The second layers E2-1, E2-2, and E2-3 may include any one among Ag, Mg, Cu, Al, Pt, Pd, Au, Ni, Nd, Ir, Cr, Li, Ca, LiF/Ca, LiF/Al, Mo, and Ti having a high reflectance. For example, the second layers E2-1, E2-2, and E2-3 may include Ag.

The transparent electrodes TE1, TE2, and TE3 may include a first transparent electrode TE1 included in the first light-emitting element ED-1, a second transparent electrode TE2 included in the second light-emitting element ED-2, and a third transparent electrode TE3 included in the third light-emitting element ED-3.

The first transparent electrode TE1, the second transparent electrode TE2, and the third transparent electrode TE3 may each include a transparent conductive oxide. The first transparent electrode TE1, the second transparent electrode TE2, and the third transparent electrode TE3 may each include at least one selected from a group including indium-tin oxide (ITO), indium-zinc oxide (IZO), indium-gallium-zinc oxide (IGZO), zinc oxide (ZnOₓ), or indium oxide (In₂O₃), and aluminum-doped zinc oxide (AZO). For example, the first transparent electrode TE1, the second transparent electrode TE2, and the third transparent electrode TE3 may each include indium-tin oxide (ITO), or indium-zinc oxide (IZO).

The inorganic film TCF is located between at least some of the reflective electrodes RE1, RE2, and RE3, and the transparent electrodes TE1, TE2, and TE3. The inorganic film TCF may be located between at least some of the reflective electrodes RE1, RE2, and RE3 and the transparent electrodes TE1, TE2, and TE3, and thus may control a resonance distance of each of the first to third light-emitting elements ED-1, ED-2, and ED-3. The inorganic film TCF may be located between at least some of the reflective electrodes RE1, RE2, and RE3 and the transparent electrodes TE1, TE2, and TE3, and thus the reflective electrodes RE1, RE2, and RE3 and the transparent electrodes TE1, TE2, and TE3 may be spaced apart from each other, thereby being designed to make an optimum resonance frequency causing optical resonance by light respectively emitted by the first to third light-emitting elements ED-1, ED-2, and ED-3.

Meanwhile, unlike what is illustrated in FIGS. 4, 5A, and 5B, the lower electrodes LE1, LE2, and LE3 may include only the reflective electrodes RE1, RE2, and RE3, and may not include the transparent electrodes TE1, TE2, and TE3. The lower electrodes LE1, LE2, and LE3 may include the reflective electrodes RE1, RE2, and RE3, and the reflective electrodes RE1, RE2, and RE3 may include, for example, titanium oxide (TiN). A least a portion of the inorganic film TCF may be located on the reflective electrodes RE1, RE2, and RE3.

The inorganic film TCF may include a first inorganic film TCF1 and a second inorganic film TCF2. The first inorganic film TCF1 is located between the first reflective electrode RE1 and the first transparent electrode TE1. The second inorganic film TCF2 may be located between the first reflective electrode RE1 and the first transparent electrode TE1. The second inorganic film TCF2 may be located between the second reflective electrode RE2 and the second transparent electrode TE2. The first inorganic film TCF1 may not be located between the second reflective electrode RE2 and the second transparent electrode TE2, and between the third reflective electrode RE3 and the third transparent electrode TE3. The second inorganic film TCF2 may not be located between the third reflective electrode RE3 and the third transparent electrode TE3.

The first inorganic film TCF1 and the second inorganic film TCF2 may be all located between the first reflective electrode RE1 and the first transparent electrode TE1, and thus the first reflective electrode RE1 and the first transparent electrode TE1 may be spaced apart from each other by a first distance D1 in a thickness direction of the display panel DP. The second inorganic film TCF2 may be located between the second reflective electrode RE2 and the second transparent electrode TE2, and thus the second reflective electrode RE2 and the second transparent electrode TE2 may be spaced apart from each other by a second distance D2 in the thickness direction of the display panel DP. The first distance D1 may be greater than the second distance D2. The inorganic film TCF may not be located between the third reflective electrode RE3 and the third transparent electrode TE3, and thus the third transparent electrode TE3 may be directly located on the third reflective electrode RE3.

The first inorganic film TCF1 may not be located between the second reflective electrode RE2 and the second transparent electrode TE2, and between the third reflective electrode RE3 and the third transparent electrode TE3, and may be spaced apart from each of the second reflective electrode RE2 and the third reflective electrode RE3. The first inorganic film TCF1 may be spaced apart from the second reflective electrode RE2 with a first gap GP1 therebetween. The first inorganic film TCF1 may be spaced apart from the third reflective electrode RE3 with a second gap GP2 therebetween. The second inorganic film TCF2 may not be located between the third reflective electrode RE3 and the third transparent electrode TE3, and may be spaced apart from the third reflective electrode RE3. The second inorganic film TCF2 may be spaced apart from the third reflective electrode RE3 with the second gap GP2 therebetween. The first gap GP1 and the second gap GP2 may be each, for example, about 2 μm or less.

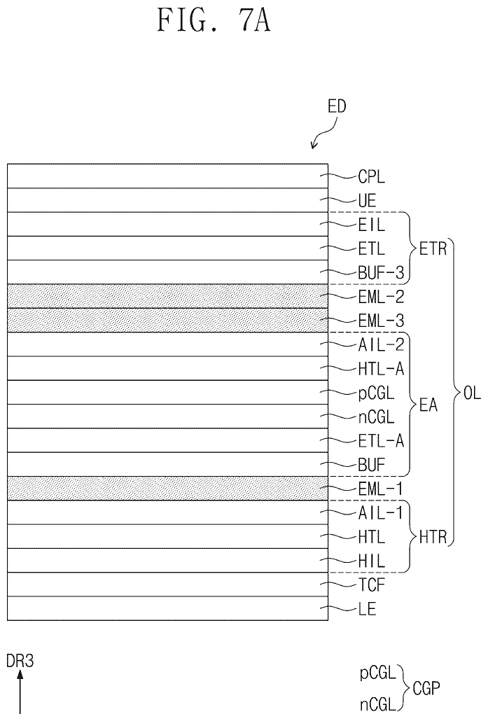

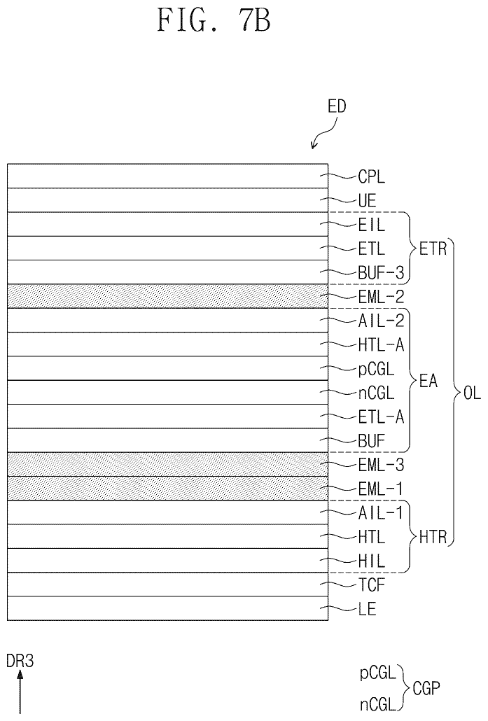

The transparent electrodes TE1, TE2, and TE3 may be in contact with the reflective electrodes RE1, RE2, and RE3. The transparent electrodes TE1, TE2, and TE3 may be in contact with the reflective electrodes RE1, RE2, and RE3 to supply charges to a hole transport region HTR (see FIG. 7A) located on the transparent electrodes TE1, TE2, and TE3. Meanwhile, since the first inorganic film TCF1 and the second inorganic film TCF2 are located between the first reflective electrode RE1 and the first transparent electrode TE1, the first transparent electrode TE1 may be in contact with the first reflective electrode RE1 through a first contact CH1 penetrating the first inorganic film TCF1 and the second inorganic film TCF2. Since the second inorganic film TCF2 is located between the second reflective electrode RE2 and the second transparent electrode TE2, the second transparent electrode TE2 may be in contact with the second reflective electrode RE2 through a second contact CH2 penetrating the second inorganic film TCF2.

The first inorganic film TCF1 may cover an upper surface and side surfaces of the first reflective electrode RE1. The first inorganic film TCF1 may entirely cover the rest of the upper surface except for the first contact CH1 and the side surfaces of the first reflective electrode RE1. The second inorganic film TCF2 may cover an upper surface and side surfaces of the second reflective electrode RE2. The second inorganic film TCF2 may entirely cover the rest of the upper surface except for the second contact CH2 and the side surfaces of the second reflective electrode RE2.

The first inorganic film TCF1 and the second inorganic film TCF2 each include an inorganic material. The first inorganic film TCF1 and the second inorganic film TCF2 may each include at least one of silicon oxide (SiOₓ), silicon nitride (SiNₓ), or silicon oxynitride (SiOₓN_{y}). The first inorganic film TCF1 and the second inorganic film TCF2 may each include, for example, silicon oxide (SiOₓ).

The display element layer DP-ED of the display panel DP may include the pixel-defining film PDL. The pixel-defining film PDL may be located on at least a portion of the lower electrodes LE1, LE2, and LE3 and on the inorganic film TCF. The pixel-defining film PDL may partially cover edges of the transparent electrodes TE1, TE2, and TE3. The pixel-defining film PDL may include a pixel opening at least partially exposing the upper surface of each of the transparent electrodes TE1, TE2, and TE3 included in the lower electrodes LE1, LE2, and LE3, and the pixel opening may define first to third light-emitting regions PXA-1, PXA-2, and PXA-3.

The pixel-defining film PDL may include an inorganic material. The pixel-defining film PDL may include at least one of silicon oxide (SiOₓ), silicon nitride (SiNₓ), or silicon oxynitride (SiOₓN_{y}). The pixel-defining film PDL may include, for example, silicon oxide (SiOₓ).

Side surfaces of the pixel-defining film PDL defining the pixel opening may each have a predetermined taper angle. The side surfaces of the pixel-defining film PDL may each have a taper angle of about 40° or more. The side surfaces of the pixel-defining film PDL may each have a taper angle of, for example, about 75° to about 90°. Since the pixel-defining film PDL include an inorganic material, the side surfaces of the pixel-defining film PDL may each have a great taper angle of about 75° or more.

The first inorganic film TCF1 and the second inorganic film TCF2 may each have a thickness of, for example, about 100 Å to about 3000 Å. The pixel-defining film PDL may have a thickness of, for example, about 500 Å to about 3000 Å.

In the first to third light-emitting elements ED-1, ED-2, and ED-3, the organic layer OL may be provided as a common layer. The organic layer OL may include at least one light-emitting layer. The first to third light-emitting elements ED-1, ED-2, and ED-3 may be light-emitting elements having a tandem structure. The organic layer OL may overlap the first to third light-emitting regions PXA-1, PXA-2, and PXA-3 and a non-light-emitting region NPXA. Meanwhile, in this specification, the wording, “one component overlaps another component” includes not only that the two components have the same area and the same shape on a plane or in a plan view, but also that the two components have different area and/or different shapes. The organic layer OL may include at least a plurality of light-emitting layers EML-1, EML-2, and EML-3 (see FIG. 7A). More detailed description for the organic layer OL will be made later.

In the first to third light-emitting elements ED-1, ED-2, and ED-3, the upper electrode UE may be provided as a common electrode. The upper electrode UE may be a common layer overlapping all of the first to third light-emitting regions PXA-1, PXA-2, and PXA-3 and the non-light-emitting region NPXA, and having an integrated shape. Meanwhile, the upper electrode UE located on the organic layer OL in this specification may mean “a cathode”

The capping layer CPL may be located on the upper electrode UE. The capping layer CPL may include a single layer or a multiple layer. The capping layer CPL may be an organic layer or an inorganic layer. For example, when the capping layer CPL includes an inorganic material, the inorganic material may include an alkaline metal compound such as LiF, an alkaline earth metal compound such as MgF₂, SiON, SiNₓ, SiO_{y}, or the like. Unlike this, when the capping layer CPL includes an organic material, the organic material may include a-NPD, NPB, TPD, m-MTDATA, Alq₃, CuPc, TPD15 (N4,N4,N4′,N4′-tetra(biphenyl-4-yl)biphenyl-4,4′-diamine), TCTA (4,4′,4″-tris(carbazol-9-yl)triphenylamine), or the like, or may include an epoxy resin, or acrylate such as methacrylate.

The encapsulation layer TFE may be located on the display element layer DP-ED. The encapsulation layer TFE may protect the display element layer DP-ED from foreign matters such as moisture, oxygen, and dust particles. The encapsulation layer TFE may include at least one inorganic film (hereinafter, inorganic encapsulation film). In addition, the encapsulation layer TFE may include at least one organic film (hereinafter, organic encapsulation film) and at least one inorganic encapsulation film.

The inorganic encapsulation film may protect the display element layer DP-ED from moisture/oxygen, and the organic encapsulation film may protect the display element layer DP-ED from foreign matters such as dust particles. The inorganic encapsulation film may include silicon nitride, silicon oxynitride, silicon oxide, titanium oxide, aluminum oxide, or the like, but is not specially limited thereto. The organic encapsulation film may include an acrylic compound, an epoxy-based compound, or the like. The organic encapsulation film may include an organic photo-synthesizable material, but is not specially limited thereto.

The color filter layer CFL may be located on the encapsulation layer TFE. The color filter layer CFL may include a first filter CF1 corresponding to the first light-emitting region PXA-1, a second filter CF2 corresponding to the second light-emitting region PXA-2, and a third filter CF3 corresponding to the third light-emitting region PXA-3. According to some embodiments, the color filter layer CFL may further include a light-blocking portion. The light-blocking portion may be a black matrix. The light-blocking portion may be formed including an organic light-blocking material or an inorganic light-blocking material including a black pigment or a black dye. The light-blocking portion may prevent a light leak phenomenon, and may divide adjacent filters CF1, CF2, and CF3.

The first to third filters CF1, CF2, and CF3 may each include a polymeric photosensitive resin and a colorant. In this specification, the colorant includes a pigment and a dye. A red colorant includes a red pigment and a red dye, a green colorant includes a green pigment and a green dye, and a blue colorant includes a blue pigment and a blue dye.

In FIG. 4, the first filter CF1 may include the red pigment and the red dye, the second filter CF2 may include the green pigment and the green dye, and the third filter CF3 may include the blue pigment and the blue dye. That is, the first filter CF1 located on the first light-emitting element ED-1 may include the red colorant, the second filter CF2 located on the second light-emitting element ED-2 may include the green colorant, and the third filter CF3 located on the third light-emitting element ED-3 may include the blue colorant.

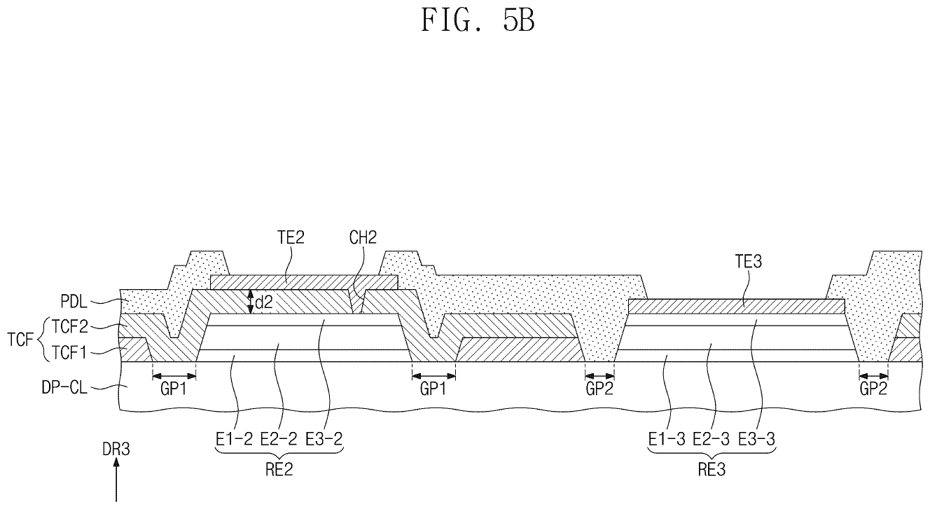

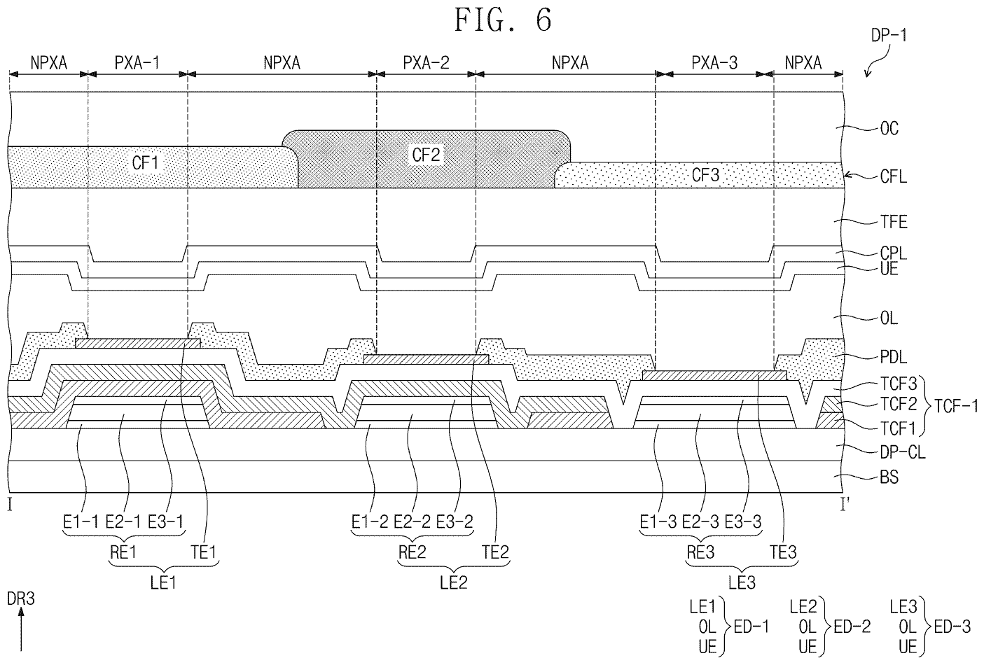

FIG. 6 is a cross-sectional view of a display panel according to some embodiments of the present disclosure. FIG. 6 illustrates a display panel DP-1 according to some embodiments of the present disclosure. Hereinafter, in description of the display panel DP-1 according to some embodiments of the present disclosure, the same numerals or symbols will be given to the same configurations as those described above, and some repetitive detailed description thereof may be omitted.

Referring to FIG. 6, in the display panel DP-1 according to some embodiments, an inorganic film TCF-1 included in a display element layer DP-ED may include a first inorganic film TCF1, a second inorganic film TCF2, and a third inorganic film TCF3.

The first inorganic film TCF1 is located between a first reflective electrode RE1 and a first transparent electrode TE1. The second inorganic film TCF2 may be located between the first reflective electrode RE1 and the first transparent electrode TE1. The second inorganic film TCF2 may be located between a second reflective electrode RE2 and a second transparent electrode TE2. The third inorganic film TCF3 may be located between the first reflective electrode RE1 and the first transparent electrode TE1. The third inorganic film TCF3 may be located between the second reflective electrode RE2 and the second transparent electrode TE2. The third inorganic film TCF3 may be located between a third reflective electrode RE3 and a third transparent electrode TE3. The third inorganic film TCF3 may be provided as a common layer.

The first inorganic film TCF1 may not be located between the second reflective electrode RE2 and the second transparent electrode TE2, and between the third reflective electrode RE3 and the third transparent electrode TE3. The second inorganic film TCF2 may not be located between the third reflective electrode RE3 and the third transparent electrode TE3.

The first inorganic film TCF1 to the third inorganic film TCF3 may be all located between the first reflective electrode RE1 and the first transparent electrode TE1, the second inorganic film TCF2 and the third inorganic film TCF3 may be located between the second reflective electrode RE2 and the second transparent electrode TE2, and the third inorganic film TCF3 may be located between the third reflective electrode RE3 and the third transparent electrode TE3.

A display panel according to some embodiments of the present disclosure electrode in at least one lower electrode, and thus may have a resonance structure appropriate for a wavelength of light emitted by a light-emitting element, thereby performing excellent display resolution and improved light-emitting efficiency. For example, because according to some embodiments of the present disclosure, a thickness of a first resonance electrode in the light-emitting element according to the wavelength of light to be output is designed, a resonance distance may be controlled to have an optimum resonance frequency, thereby having excellent display resolution. Meanwhile, the inorganic film provided to control the resonance distance has a structure overlapping a light-emitting element, and spaced apart from a reflective electrode of another light-emitting element. For example, as illustrated in FIG. 4, the first inorganic film TCF1 located between the first reflective electrode RE1 and the first transparent electrode TE1 has a structure spaced apart from the second reflective electrode RE2 and the third reflective electrode RE3. Accordingly, a large step difference in a pixel-defining film including the inorganic material may be prevented, and thus a limitation of disconnection of an upper electrode located on the pixel-defining film may be prevented. Accordingly, the display panel according to some embodiments of the present disclosure may perform high resolution and high light-emitting efficiency through excellent optical resonance designing, and durability and reliability of the display panel may be improved.

FIGS. 7A and 7B are cross-sectional views of a light-emitting element according to some embodiments of the present disclosure. FIGS. 7A and 7B specifically illustrate an organic layer OL included in a light-emitting element ED according to some embodiments of the present disclosure. Description for the light-emitting element ED to be described later in FIGS. 7A and 7B may be identically applied to each of the first to third light-emitting elements ED-1, ED-2, and ED-3 in FIG. 4.

Referring to FIGS. 7A and 7B, the organic layer OL according to some embodiments may include a hole transport region HTR, a first light-emitting layer EML-1, an auxiliary light-emitting portion EA, a second light-emitting layer EML-2, a third light-emitting layer EML-3, and an electron transport region ETR. In the light-emitting element ED, the hole transport region HTR, the first light-emitting layer EML-1, the auxiliary light-emitting portion EA, the second light-emitting layer EML-2, the third light-emitting layer EML-3, and the electron transport region ETR may be provided as common layers. The light-emitting element ED including the first light-emitting layer EML-1, the second light-emitting layer EML-2, and the third light-emitting layer EML-3 that respectively generate light having different wavelength regions may emit white light. According to some embodiments, a thickness of each of the hole transport region HTR, the auxiliary light-emitting portion EA, and the electron transport region ETR included in the light-emitting element ED may be supplied so that red light, green light, or blue light has a n-th resonance. Meanwhile, a thickness of the inorganic film TCF (see FIG. 4) described above may be also supplied so that the red light, the green light or the blue light emitted by each of the light-emitting layers EML-1, EML-2, and EML-3 of the light-emitting element ED has a n-th resonance.

The first to third light-emitting layers EML-1, EML-2, and EML-3 provided as common layers may be deposited without any mask, and thus may form a pixel having a smaller area. In the display panel DP according to some embodiments, more pixels having a smaller area may be arranged on a plane or in a plan view, thereby enabling relatively high resolution.

In the light-emitting element ED, the hole transport region HTR may be provided on the lower electrode LE and the inorganic film TCF. Meanwhile, the lower electrode LE in FIGS. 7A and 7B may mean the lower electrodes LE1, LE2, and LE3 described above in FIGS. 4, 5A, and 5B. The hole transport region HTR may have a single layer composed of a single material, a single layer composed of a plurality of different materials, or a multi-layered structure having a plurality of layers composed of a plurality of different materials. For example, the hole transport region HTR may include a phthalocyanine compound such as copper phthalocyanine, DNTPD (N1,N1′-([1,1′-biphenyl]-4,4′-diyl)bis(N1-phenyl-N4,N4-di-m-tolylbenzene-1,4-diamine)), m-MTDATA (4,4′,4″-[tris(3-methylphenyl)phenylamino]triphenylamine), TDATA (4,4′,4″-tris(N,N-diphenylamino)triphenylamine), 2-TNATA (4,4′,4″-tris[N(2-naphthyl)-N-phenylamino]-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/camphor sulfonicacid), PANI/PSS (polyaniline/poly(4-styrenesulfonate)), NPB (N,N′-di(naphthalene-1-yl)-N,N′-diphenyl-benzidine), TPAPEK (polyetherketone containing triphenylamine), 4-isopropyl-4′-methyldiphenyliodonium[tetrakis(pentafluorophenyl)borate], HATCN (dipyrazino[2,3-f: 2′,3′-h]quinoxaline-2,3,6,7,10,11-hexacarbonitrile), or the like.

In addition, the hole transport region HTR may include a carbazole-based derivative such as N-phenylcarbazole and polyvinylcarbazole, a fluorene-based derivative, a triphenylamine-based derivative such as TPD (N,N′-bis(3-methylphenyl)-N,N′-diphenyl-[1,1′-biphenyl]-4,4′-diamine) and TCTA (4,4′,4″-tris(N-carbazolyl)triphenylamine), TAPC (4,4′-cyclohexylidene bis[N, N-bis(4-methylphenyl)benzenamine]), HMTPD (4,4′-bis[N,N′-(3-tolyl)amino]-3,3′-dimethylbiphenyl), CzSi (9-(4-tert-butylphenyl)-3,6-bis(triphenylsilyl)-9H-carbazole), CCP (9-phenyl-9H-3,9′-bicarbazole), mCP (1,3-bis(N-carbazolyl)benzene), mDCP (1,3-bis(1,8-dimethyl-9H-carbazol-9-yl)benzene), or the like.

The hole transport region HTR may further include a charge generation material so as to improve a conductive property, as well as a material described above. The charge generation material may be uniformly or non-uniformly dispersed in the hole transport region HTR. The charge generation material may be, for example, p-type dopants. The p-type dopants may include at least one of a halogenated metal compound, a quinone derivative, a metal oxide, or a cyano-containing compound, but is not limited thereto. For example, the p-type dopant may be a halogenated metal compound such as CuI and RbI, a quinone derivative such as TCNQ (tetracyanoquinodimethane) and F4-TCNQ (2,3,5,6-tetrafluoro-7,7′8,8-tetracyanoquinodimethane), a metal oxide such as tungsten oxide and molybdenum oxide, a cyano-containing compound such as HATCN (dipyrazino[2,3-f: 2′,3′-h]quinoxaline-2,3,6,7,10,11-hexacarbonitrile) and NDP9 (4-[[2,3-bis[cyano-(4-cyano-2,3,5,6-tetrafluorophenyl)methylidene]cyclopropylidene]-cyanomethyl]-2,3,5,6-tetrafluorobenzonitrile), but embodiments according to the present disclosure are not limited thereto.

The hole transport region HTR may include a hole injection layer HIL, a first hole transport layer HTL, and a first sub-hole control layer AIL-1 sequentially stacked. Unlike what is illustrated, at least one of the hole injection layer HIL, the first hole transport layer HTL, or the first sub-hole control layer AIL-1 may be omitted. The hole injection layer HIL, the first hole transport layer HTL, and the first sub-hole control layer AIL-1 may include compounds of the hole transport region HTR described above.

The first sub-hole control layer AIL-1 may be located adjacent to the first light-emitting layer EML-1 that generates first light. The first sub-hole control layer AIL-1 may be formed to have a HOMO (highest occupied molecular orbital) energy level and a LUMO (lowest unoccupied molecular orbital) energy level facilitating movement of a hole. Accordingly, a driving voltage of the light-emitting element ED including the first sub-hole control layer AIL-1 may be prevented from increasing. In addition, the first sub-hole control layer AIL-1 may block an electron from moving from the first light-emitting layer EML-1 to the hole transport region HTR. Accordingly, the display panel DP including the light-emitting element ED including the first sub-hole control layer AIL-1 may have an improved display lifetime.

The electron transport region ETR may be provided on the auxiliary light-emitting portion EA. The electron transport region ETR may have a single layer composed of a single material, a single layer composed of a plurality of different materials, or a multi-layered structure having a plurality of layers composed of a plurality of different materials.

For example, the electron transport region ETR may include an anthracene-based compound, but is not limited thereto. The electron transport region ETR may include Alq₃ (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAIq (bis(2-methyl-8-quinolinolato-N1,08)-(1,1′-biphenyl-4-olato)aluminum), Bebq2 (berylliumbis(benzoquinolin-10-olate)), ADN (9,10-di(naphthalene-2-yl)anthracene), BmPyPhB (1,3-Bis[3,5-di(pyridin-3-yl)phenyl]benzene), and a mixture thereof.

In addition, the electron transport region ETR may include a halogenated metal such as LiF, NaCl, CsF, RbCI, RbI, CuI, KI, a lanthanide metal such as Yb, or a co-deposition material of the above halogenated metal and the lanthanide metal. For example, the electron transport region ETR may include KI:Yb, RbI:Yb, LiF:Yb or the like as the co-deposition material. Meanwhile, a metal oxide such as Li₂O and BaO, Liq (8-hydroxyl-lithium quinolate), or the like may be used as the electron transport region ETR, but embodiments according to the present disclosure are not limited thereto. The electron transport region ETR may be also composed of a mixture of an electron transport material and an insulating organometal salt. The organometal salt may have an energy band gap of about 4 eV or more. For example, the organometal salt may include metal acetate, metal benzoate, metal acetoacetate, metal acetylacetonate, or metal stearate.

The electron transport region ETR may further include, as well as a material describe above, at least one of BCP (2,9-dimethyl-4,7-diphenyl-1,10-phenanthroline), TSPO1 (diphenyl(4-(triphenylsilyl)phenyl)phosphine oxide), or Bphen (4,7-diphenyl-1,10-phenanthroline), but embodiments according to the present disclosure are not limited thereto.

The electron transport region ETR may include a buffer layer BUF, a first electron transport layer ETL, and an electron injection layer EIL sequentially stacked. Unlike what is illustrated, at least one of the buffer layer BUF, the first electron transport layer ETL, or the electron injection layer EIL may be omitted. The buffer layer BUF, the first electron transport layer ETL, and the electron injection layer EIL may include compounds of the electron transport region ETR described above. The buffer layer BUF may block a hole from moving from the third light-emitting layer EML-3 to the electron transport region ETR.

The auxiliary light-emitting portion EA located between the first light-emitting layer EML-1 and the second light-emitting layer EML-2 may include a buffer layer BUF, a second electron transport layer ETL-A, a first charge generation layer nCGL, a second charge generation layer pCGL, a second hole transport layer HTL-A, and a second sub-hole control layer AIL-2. The first charge generation layer nCGL may be an n-type charge generation layer, and the second charge generation layer pCGL may be a p-type charge generation layer. Unlike what is illustrated, at least one of the buffer layer BUF, the second electron transport layer ETL-A, the first charge generation layer nCGL, the second charge generation layer pCGL, the second hole transport layer HTL-A, or the second sub-hole control layer AIL-2 may be omitted.

The second sub-hole control layer AIL-2 may include a material different form the first sub-hole control layer AIL-1. The second sub-hole control layer AIL-2 may include a material that helps generate second light of the second light-emitting layer EML-2, or a material that helps generate third light of the third light-emitting layer EML-3. The first sub-hole control layer AIL-1 may include a material that helps generate first light of the first light-emitting layer EML-1, but embodiments according to the present disclosure are not limited thereto. The first sub-hole control layer AIL-1 and the second sub-hole control layer AIL-2 may include the same material.

The second sub-hole control layer AIL-2 may be located adjacent to the third light-emitting layer EML-3 that generates the third light, or the second light-emitting layer EML-2 that generates the second light. The second sub-hole control layer AIL-2 may be formed to have a HOMO (highest occupied molecular orbital) energy level and a LUMO (lowest unoccupied molecular orbital) energy level facilitating movement of a hole. Accordingly, a driving voltage of the light-emitting element ED including the second sub-hole control layer AIL-2 may be prevented from increasing. In addition, the second sub-hole control layer AIL-2 may block an electron from moving from the second light-emitting layer EML-2 or the third light-emitting layer EML-3 to the second hole transport layer HTL-A. Accordingly, the display panel DP including the light-emitting element ED including the second sub-hole control layer AIL-2 may have an improved display lifetime.

The upper electrode UE may be provided on the organic layer OL. Meanwhile, the upper electrode UE in FIGS. 7A and 7B may mean the upper electrode UE described in FIG. 4. The upper electrode UE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof. The upper electrode UE may be a transmissive electrode, a semi-transmissive electrode, or a reflective electrode. When the upper electrode UE is the transmissive electrode, the upper electrode UE may be composed of a transparent metal oxide, for example, indium-tin oxide (ITO), indium-zinc oxide (IZO), zinc oxide (ZnO), indium-tin-zinc oxide (IGZO), or the like.

When the upper electrode UE is the semi-transmissive electrode or the reflective electrode, the upper electrode UE may include Ag, Mg, Cu, Al, Pt, Pd, Au, Ni, Nd, Ir, Cr, Li, Ca, LiF/Ca, LiF/Al, Mo, Ti, Yb, or W, or a compound or mixture including the same (for example, AgMg, AgYb, or MgYb). Alternatively, the upper electrode UE may have a structure having a plurality of layers including a reflective film or a semi-transmissive film formed of the above material, and a transparent conductive film formed of indium-tin oxide (ITO), indium-zinc oxide (IZO), zinc oxide (ZnO), indium-tin-zinc oxide (ITZO), or the like. For example, the upper electrode UE may include the metal material described above, a combination of two or more metal materials selected from the metal materials described above, oxides of the metal materials described above, or the like.

The capping layer CPL may be provided on the upper electrode UE. The capping layer CPL may include a single layer or a multiple layer. The capping layer CPL may be an organic layer or an inorganic layer. For example, when the capping layer CPL includes an inorganic material, the inorganic material may include an alkali metal compound such LiF, an alkali earth metal compound such as MgF₂, SiON, SiNₓ, SiO_{y}, or the like. Unlike this, when the capping layer CPL includes an organic material, the organic material may include α-NPD, NPB, TPD, m-MTDATA, Alq₃, CuPc, TPD15 (N4,N4,N4′,N4′-tetra(biphenyl-4-yl)biphenyl-4,4′-diamine), TCTA (4,4′,4″-tris(carbazol-9-yl)triphenylamine), or the like, or may include an epoxy resin, or acrylate such as methacrylate.

Referring to FIG. 7A, the first light-emitting layer EML-1 according to some embodiments may be located on the hole transport region HTR. The second light-emitting layer EML-2 may be located on the auxiliary light-emitting portion EA. The third light-emitting layer EML-3 may be located between the second light-emitting layer EML-2 and the auxiliary light-emitting portion EA. Referring to FIG. 7B, the first light-emitting layer EML-1 according to some embodiments may be located on the hole transport region HTR, the second light-emitting layer EML-2 may be located on the auxiliary light-emitting portion EA, and the third light-emitting layer EML-3 may be located between the first light-emitting layer EML-1 and the auxiliary light-emitting portion EA. However, this is an example, and embodiments according to the present disclosure are not limited thereto.

The first light-emitting layer EML-1 may generate blue light, the second light-emitting layer EML-2 may generate red light, and the third light-emitting layer EML-3 may generate green light. Unlike this, the first light-emitting layer EML-1 may generate green light, the second light-emitting layer EML-2 may generate blue light, and the third light-emitting layer EML-3 may generate red light. Alternatively, the first light-emitting layer EML-1 may generate red light, the second light-emitting layer EML-2 may generate green light, and the third light-emitting layer EML-3 may generate blue light.

Hereinafter, a method for manufacturing a display panel according to some embodiments of the present disclosure will be described in more detail with reference to the drawings. In description for the method for manufacturing a display panel according to some embodiments, some duplicated description with those made with the display panel according to some embodiments described above may be omitted.

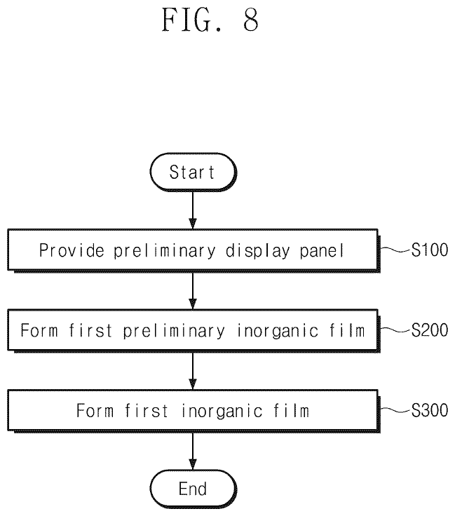

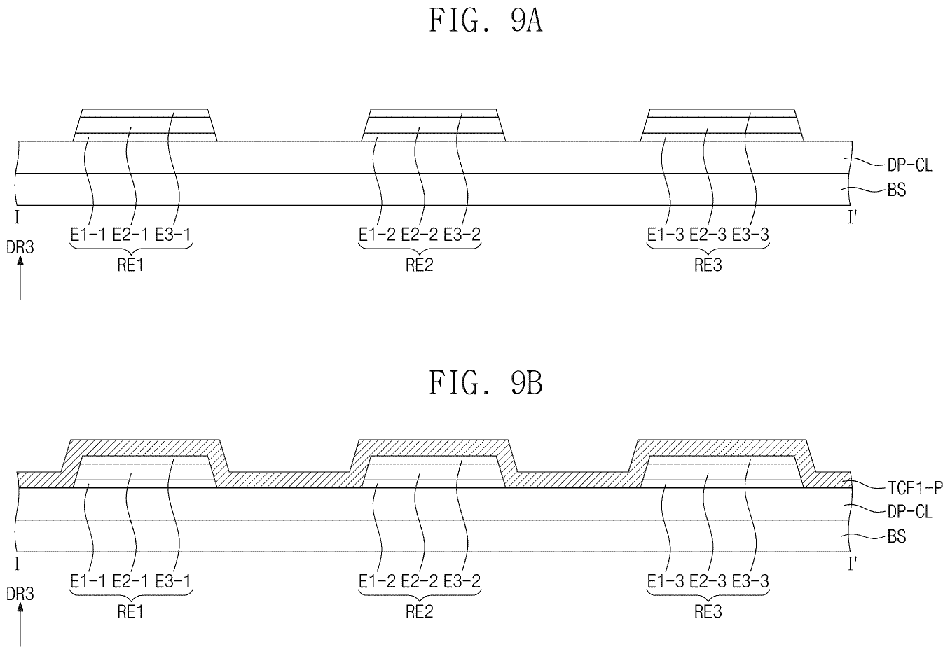

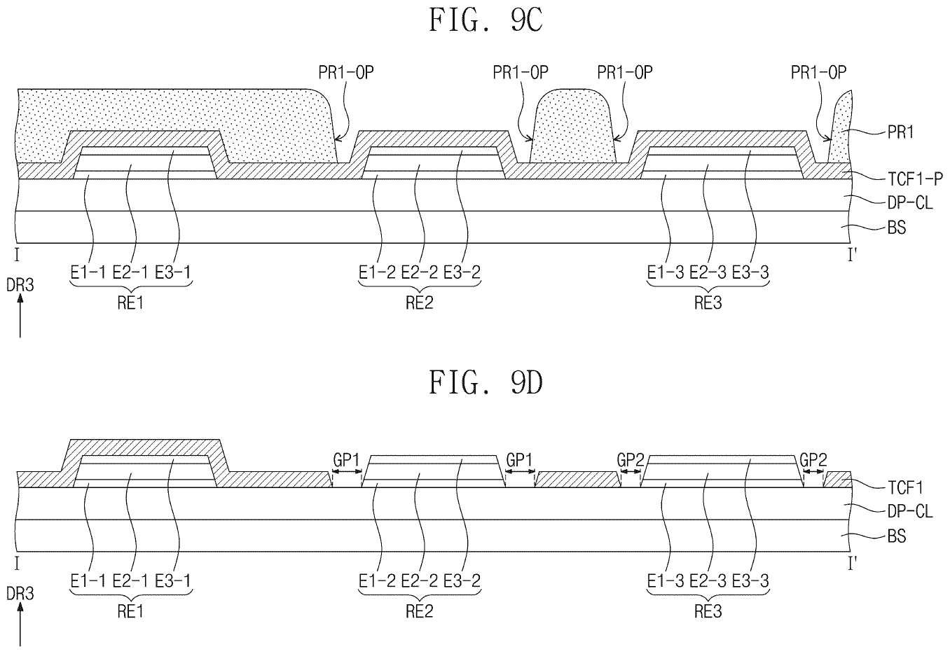

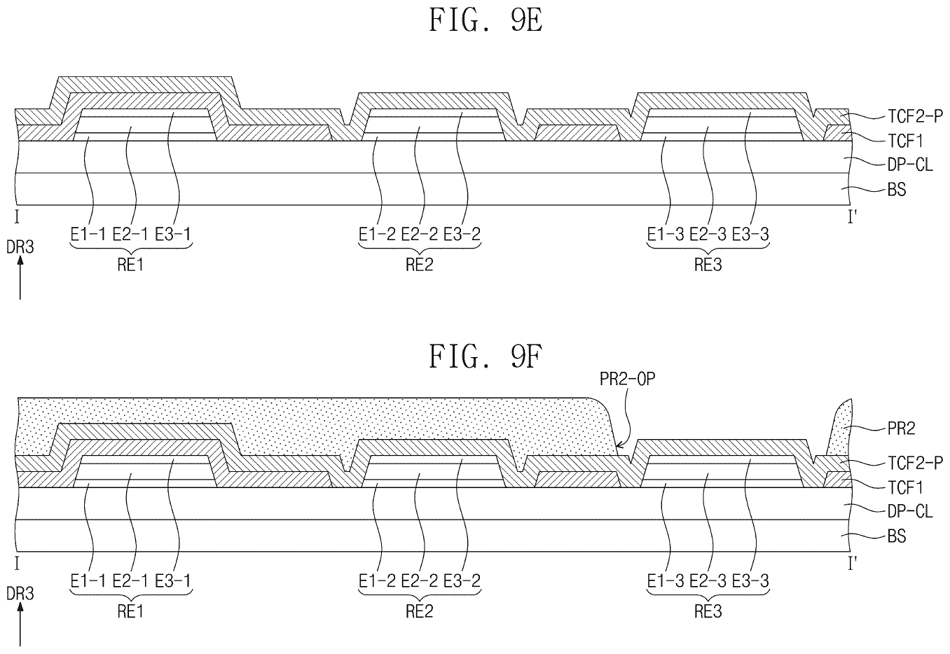

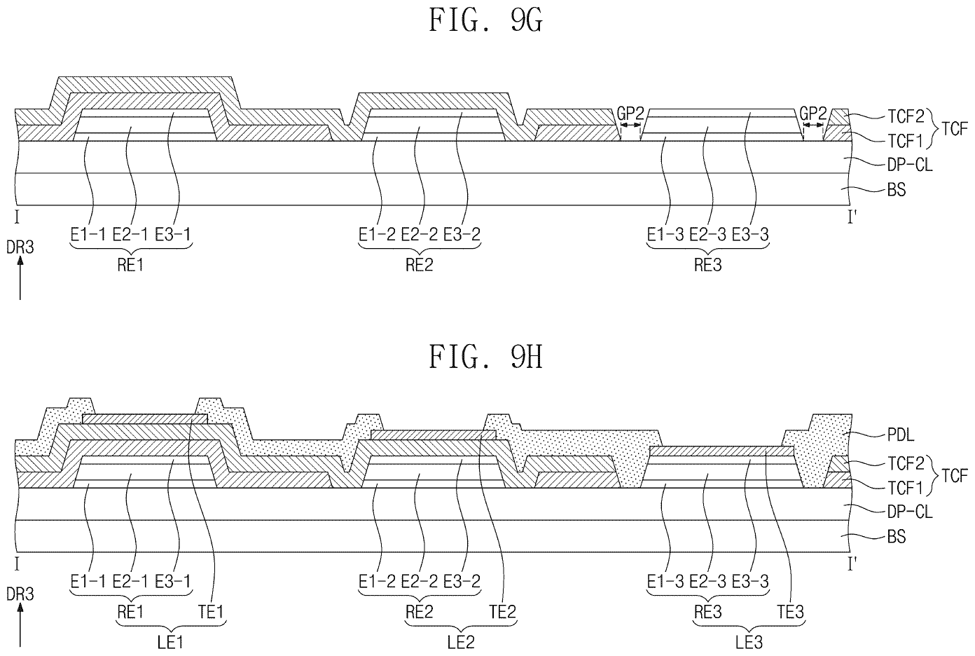

FIG. 8 is a flowchart of the method for manufacturing a display panel according to some embodiments of the present disclosure. FIGS. 9A to 9H are cross-sectional view of some operations of the method for manufacturing a display panel according to some embodiments of the present disclosure. FIGS. 9A to 9H respectively illustrate states of some operations of the method for manufacturing a display panel on a cross-section corresponding in FIG. 4.

Referring to FIG. 8, the method for manufacturing a display panel includes an operation (S100) of providing a preliminary display panel including a base layer, a first reflective electrode, and a second reflective electrode, an operation (S200) of forming a first preliminary inorganic film that covers each of the first reflective electrode and the second reflective electrode, and an operation (S300) of forming a first inorganic film by patterning the first preliminary inorganic film to partially remove the first preliminary inorganic film formed on the second reflective electrode.

Referring to FIGS. 8, 9A, and 9B together, the method for manufacturing a display panel according to some embodiments includes the operation (S100) of providing a preliminary display panel including a base layer BS, and a plurality of reflective electrodes RE1, RE2, and RE3 located on the base layer BS, and the operation (S200) of forming a first preliminary inorganic film by depositing an inorganic material on the preliminary display panel.

In the preliminary display panel, a circuit layer DP-CL may be located on the base layer BS, and the plurality of reflective electrodes RE1, RE2, and RE3 may be located on the circuit layer DP-CL.

The base layer BS may be a rigid substrate, or a flexible substrate bendable, foldable, or rollable. The base layer BS may be a glass substrate, a metal substrate, a polymer substrate, or the like. However, embodiments according to the present disclosure are not limited thereto, and the base layer BS may be an inorganic layer, an organic layer, or a composite material layer. The circuit layer DP-CL may include an insulating layer, a semiconductor pattern, a conductive pattern, a signal line, etc. After an insulating layer, a semiconductor layer, and a conductive layer are formed on the base layer BS in a method such as coating or deposition, the insulating layer, the semiconductor layer, and the conductive layer may be selectively patterned through a plurality times of photolithography processes. Thereafter, the semiconductor pattern, the conductive pattern, and the signal line included in the circuit layer DP-CL may be formed.

The reflective electrodes RE1, RE2, and RE3 may be located on the circuit layer DP-CL, and may include a first reflective electrode RE1, a second reflective electrode RE2, and a third reflective electrode RE3. The first reflective electrode RE1, the second reflective electrode RE2, and the third reflective electrode RE3 may be arranged to be spaced apart from each other. The first reflective electrode RE1, the second reflective electrode RE2, and the third reflective electrode RE3 may be all located on the circuit layer DP-CL. The first reflective electrode RE1, the second reflective electrode RE2, and the third reflective electrode RE3 may be located on the uppermost layer of a plurality of insulating layers included in the circuit layer DP-CL.

The first reflective electrode RE1, the second reflective electrode RE2, and the third reflective electrode RE3 may each include first layers E1-1, E1-2, and E1-3, second layers E2-1, E2-2, and E2-3, and third layers E3-1, E3-2, and E3-3 sequentially stacked. The first reflective electrode RE1, the second reflective electrode RE2, and the third reflective electrode RE3 may each include an electrode having a three-layered structure in which the first layers E1-1, E1-2, and E1-3, the second layers E2-1, E2-2, and E2-3, and the third layers E3-1, E3-2, and E3-3 are stacked.

A first preliminary inorganic film TCF1-P may be formed by depositing an inorganic material. The first preliminary inorganic film TCF1-P may be formed to cover an upper surface and side surfaces of each of the first reflective electrode RE1, the second reflective electrode RE2, and the third reflective electrode RE3. The inorganic material forming the first preliminary inorganic film TCF1-P may include at least one of silicon oxide (SiOₓ), silicon nitride (SiNₓ), or silicon oxynitride (SiOₓN_{y}).

Referring to FIGS. 8, 9B to 9D together, the method for manufacturing a display panel according to some embodiments includes the operation (S300) of forming a first inorganic film TCF1 by patterning the first preliminary inorganic film TCF1-P.

An operation of patterning the first preliminary inorganic film TCF1-P may include an operation of partially removing the first preliminary inorganic film TCF1-P using a photoresist pattern as a mask. In the method for manufacturing a display panel according to some embodiments, after a first photoresist pattern PR1 is formed on the first preliminary inorganic film TCF1-P, the first preliminary inorganic film TCF1-P may be partially removed using the first photoresist pattern PR1 as a mask.

A first opening PR1-OP may be provided in the first photoresist pattern PR1, and the first preliminary inorganic film TCF1-P corresponding to the first opening PR1-OP may be partially removed. The first opening PR1-OP may be provided to overlap each of the second reflective electrode RE2 and the third reflective electrode RE3. Accordingly, portions of the first preliminary inorganic film TCF1-P respectively overlapping the second reflective electrode RE2, and the third reflective electrode RE3 may be removed, and thus the first inorganic film TCF1 may be formed. Since the first opening PR1-OP is provided to overlap not only portions in which the second reflective electrode RE2 and the third reflective electrode RE3 are respectively arranged, but also portions which are respectively adjacent to the second reflective electrode RE2 and the third reflective electrode RE3, the patterned first inorganic film TCF1 may be formed to be spaced apart from each of the second reflective electrode RE2 and the third reflective electrode RE3. The first inorganic film TCF1 may be spaced apart from the second reflective electrode RE2 with a first gap GP1 therebetween, and may be spaced apart from the third reflective electrode RE3 with a second gap GP2 therebetween.

The operation of patterning the first preliminary inorganic film TCF1-P may be performed through a dry-etching process. The operation of patterning the first preliminary inorganic film TCF1-P may include an operation of partially removing the first preliminary inorganic film TCF1-P corresponding to the first opening PR1-OP through the dry-etching process.

Referring to FIGS. 9D and 9E together, the method for manufacturing a display panel according to some embodiments may include an operation of forming a second preliminary inorganic film TCF2-P after the operation of forming the first inorganic film TCF1.

The second preliminary inorganic film TCF2-P may be formed by depositing an inorganic material. The second preliminary inorganic film TCF2-P may be formed to cover an upper portion of the first inorganic film TCF1, and to cover an exposed upper surface and exposed side surfaces of each of the second reflective electrode RE2 and the third reflective electrode RE3. The inorganic material forming the second preliminary inorganic film TCF2-P may include at least one of silicon oxide (SiOₓ), silicon nitride (SiNₓ), or silicon oxynitride (SiOₓN_{y}).

Referring to FIGS. 9E to 9G together, the method for manufacturing a display panel according to some embodiments may include an operation of forming a second inorganic film TCF2 by patterning the second preliminary inorganic film TCF2-P.

An operation of patterning the second preliminary inorganic film TCF2-P may include an operation of partially removing the second preliminary inorganic film TCF2-P using a photoresist pattern as a mask. In the method for manufacturing a display panel according to some embodiments, after a second photoresist pattern PR2 is formed on the second preliminary inorganic film TCF2-P, the second preliminary inorganic film TCF2-P may be partially removed using the second photoresist pattern PR2 as a mask.

A second opening PR2-OP may be provided in the second photoresist pattern PR2, and the second preliminary inorganic film TCF2-P corresponding to the second opening PR2-OP may be partially removed. The second opening PR2-OP may be provided to overlap the third reflective electrode RE3. Accordingly, the second preliminary inorganic film TCF2-P overlapping the third reflective electrode RE3 may be partially removed, and thus the second inorganic film TCF2 may be formed. Since the second opening PR2-OP is provided to overlap not only a portion in which the third reflective electrode RE3 is located, but also a portion which is adjacent to the third reflective electrode RE3, the patterned second inorganic film TCF2 may be formed to be spaced apart from the third reflective electrode RE3. The second inorganic film TCF2 may be spaced apart from the third reflective electrode RE3 with the second gap GP2 therebetween.

The operation of patterning the second preliminary inorganic film TCF2-P may be performed through a dry-etching process. The operation of patterning the second preliminary inorganic film TCF2-P may include an operation of partially removing the second preliminary inorganic film TCF2-P corresponding to the second opening PR2-OP through the dry-etching process.

Referring to FIGS. 9G and 9H, after the operation of forming the second inorganic film TCF2, an operation of forming transparent electrodes TE1, TE2, and TE3 and an operation of forming a pixel-defining film PDL may be further included.

The transparent electrodes TE1, TE2, and TE3 may include a first transparent electrode TE1 located on the first reflective electrode RE1, a second transparent electrode TE2 located on the second reflective electrode RE2, and a third transparent electrode TE3 located on the third reflective electrode RE3. The first transparent electrode TE1 may be located on the first inorganic film TCF1 and the second inorganic film TCF2. The second transparent electrode TE2 may be located on the second inorganic film TCF2. The third transparent electrode TE3 may be directly located on the third reflective electrode RE3.

The pixel-defining film PDL may be formed on at least a portion of the lower electrodes LE1, LE2, and LE3 and on the inorganic film TCF. The pixel-defining film PDL may be formed to partially cover edges of the transparent electrodes TE1, TE2, and TE3. The pixel-defining film PDL may be formed through an inorganic material. The pixel-defining film PDL may be formed through at least one of silicon oxide (SiOₓ), silicon nitride (SiNₓ), or silicon oxynitride (SiOₓN_{y}).

Some embodiments of the present disclosure include a display panel in which a distance between lower electrodes thereof is narrow may have a relatively high resolution, and includes an inorganic film located between a reflective electrode and a transparent electrode in at least one lower electrode to have a resonance structure appropriate for a wavelength of light emitted by a light-emitting element, thereby performing excellent display resolution and improved light-emitting efficiency. In addition, a large step difference in a pixel-defining film including the inorganic material may be prevented, and thus a limitation of disconnection of an upper electrode located on the pixel-defining film may be prevented. Accordingly, durability and reliability of the display panel may be relatively improved.

In the above, description has been made with reference to aspects of some embodiments of the present disclosure, but those skilled in the art or those of ordinary skill in the relevant technical field may understand that various modifications and changes may be made to the disclosed embodiments within the scope not departing from the spirit and the technology scope of the embodiments according to the present disclosure described in the claims, and their equivalents, to be described later. Therefore, the technical scope of embodiments according to the present disclosure are not limited to the contents described in the detailed description of the specification, but should be determined by the claims, and their equivalents.

What is claimed is:

1. A display panel comprising:
a base layer including a display region including a first light-emitting region, a second light-emitting region, and a non-light-emitting region, and a non-display region;
a first lower electrode on the base layer, overlapping the first light-emitting region, and including a first reflective electrode and a first transparent electrode on the first reflective electrode;
a second lower electrode on the base layer, overlapping the second light-emitting region, and including a second reflective electrode and a second transparent electrode on the second reflective electrode; and
a first inorganic film overlapping the first light-emitting region, and at least partially between the first reflective electrode and the first transparent electrode,
wherein the first inorganic film is spaced apart from the second reflective electrode with a first gap therebetween.

2. The display panel of claim 1, wherein the first inorganic film covers an upper surface and side surfaces of the first reflective electrode.

3. The display panel of claim 1, wherein the first inorganic film comprises at least one of silicon dioxide (SiOₓ), silicon nitride (SiNₓ), or silicon oxynitride (SiOₓN_{y}).

4. The display panel of claim 1, further comprising a second inorganic film overlapping the first light-emitting region and the second light-emitting region, and at least partially on the first reflective electrode and the second reflective electrode.

5. The display panel of claim 4, wherein the second inorganic film is respectively between the first reflective electrode and the first transparent electrode, and between the second reflective electrode and the second transparent electrode.

6. The display panel of claim 4, wherein the display region further comprises a third light-emitting region, and
the display panel further comprises a third lower electrode on the base layer, overlapping the third light-emitting region, and including a third reflective electrode and a third transparent electrode on the third reflective electrode.

7. The display panel of claim 6, wherein the second inorganic film is spaced apart from the third reflective electrode with a second gap therebetween.

8. The display panel of claim 6, wherein the third transparent electrode is directly on the third reflective electrode.

9. The display panel of claim 1, wherein a first distance between the first reflective electrode and the first transparent electrode in a thickness direction of the display panel is greater than a second distance between the second reflective electrode and the second transparent electrode in the thickness direction.

10. The display panel of claim 1, wherein the first lower electrode and the second lower electrode respectively comprise:
a first layer including a transparent conductive oxide;
a second layer on the first layer, and including a reflective metal material; and
a third layer on the second layer, and including a transparent conductive oxide.

11. The display panel of claim 1, further comprising a pixel-defining film at least partially covering each of the first transparent electrode and the second transparent electrode, and including an inorganic material.

12. The display panel of claim 1, further comprising:
at least one organic layer on the first transparent electrode and the second transparent electrode, and including a light-emitting layer; and
an upper electrode on the at least one organic layer.

13. The display panel of claim 12, further comprising:
an encapsulation layer on the upper electrode; and
a plurality of color filters on the encapsulation layer, and in each of the first light-emitting region and the second light-emitting region.

14. The display panel of claim 1, wherein the first reflective electrode and the second reflective electrode are spaced apart from each other in a plan view, and on a same layer.

15. The display panel of claim 1, wherein the first transparent electrode contacts the first reflective electrode through a first contact penetrating the first inorganic film.

16. A display panel comprising:
a base layer including a display region including a first light-emitting region, a second light-emitting region, a third light-emitting region, and a non-light-emitting region, and a non-display region;
a first reflective electrode on the base layer, and overlapping the first light-emitting region;
a second reflective electrode on the base layer, and overlapping the second light-emitting region;
a third reflective electrode on the base layer, and overlapping the third light-emitting region;
a first inorganic film overlapping the first light-emitting region, and at least partially on the first reflective electrode; and
a second inorganic film overlapping the first light-emitting region and the second light-emitting region, and at least partially on the second reflective electrode,
wherein the first inorganic film is spaced apart from the second reflective electrode with a first gap therebetween, and
the second inorganic film is spaced apart from the third reflective electrode with a second gap therebetween.

17. The display panel of claim 16, wherein the first inorganic film is configured to cover an upper surface and side surfaces of the first reflective electrode, and
the second inorganic film covers an upper surface and side surfaces of the second reflective electrode.

18. A method for manufacturing a display panel, the method comprising:
providing a preliminary display panel including a base layer, a first reflective electrode on the base layer, and a second reflective electrode on the base layer and spaced apart from the first reflective electrode;
forming a first preliminary inorganic film so as to respectively cover the first reflective electrode and the second reflective electrode; and
forming a first inorganic film by patterning the first preliminary inorganic film so as to partially remove the first preliminary inorganic film formed on the second reflective electrode,
wherein in the forming of the first inorganic film, the first inorganic film and the second reflective electrode are patterned to be spaced apart from each other with a first gap therebetween.

19. The method of claim 18, further comprising, after the forming of the first inorganic film:
forming a second preliminary inorganic film on the first inorganic film so as to cover the second reflective electrode; and
forming a second inorganic film by patterning the second preliminary inorganic film.

20. The method of claim 19, wherein the preliminary display panel is on the base layer, and further comprises a third reflective electrode spaced apart from the first reflective electrode and the second reflective electrode,
in the forming of the second preliminary inorganic film, the second preliminary inorganic film is formed to cover the third reflective electrode, and
in the forming of the second inorganic film, the second inorganic film and the third reflective electrode are patterned to be spaced apart from each other with a second gap there between.
